(19) United States
(12) Patent Application Publication
(10) Pub. No.: US 2022/0400590 A1
(43) Pub. Date: Dec. 15, 2022

(54) Operation of an Assembly Line

(71) Applicant: Siemens Aktiengesellschaft, München (DE)

(72) Inventors: Michael Hanisch, Hohen Neuendorf (DE); Jonas Massierer, Schulzendorf (DE); Marco Matiwe, Berlin (DE); Dennis Sommerfeld, Berlin (DE); Ulrich Wittreich, Velten, Brandenburg (DE); Kay Jarchoff, Berlin (DE); Jörg Schubert, Berlin (DE); Dirk Wormuth, Berlin (DE)

(73) Assignee: Siemens Aktiengesellschaft, München (DE)

(21) Appl. No.: 17/639,006

(22) PCT Filed: Jun. 26, 2020
(86) PCT No.: PCT/EP2020/067977

§ 371 Date: Feb. 28, 2022

(30) Foreign Application Priority Data
Aug. 29, 2019 (EP) 19194361.2

(51) Int. Cl. H05K 13/08; B23K 1/00; B23K 3/08; B23K 37/04; H05K 13/00

(52) U.S. Cl. CPC H05K 13/0817; B23K 1/0016; B23K 3/08; B23K 37/0408; H05K 13/0015; H05K 13/082; B23K 2101/42

(57) ABSTRACT

Various embodiments of the teachings herein include a device for detecting process parameters during a pass through an assembly line for assembling electronic components and/or for applying joining materials. The device may include: a carrier for transport by a conveying system of the assembly line and configured to receive a test plate; a sensor for measuring a process parameter during the pass; and a force sensor arranged to detect a force acting on the test plate during the pass.

### CROSS-REFERENCE TO RELATED APPLICATIONS

This application is a U.S. National Stage Application of International Application No. PCT/EP2020/067977 filed Jun. 26, 2020, which designates the United States of America, and claims priority to EP Application No. 19194361.2 filed Aug. 29, 2019, the contents of which are hereby incorporated by reference in their entirety.

### TECHNICAL FIELD

The present disclosure relates to assembly lines. Various embodiments of the teachings herein include devices for detecting process parameters during a pass through an assembly line and/or systems comprising a device and a test plate.

### BACKGROUND

Assembly lines for the assembly of electronic components and/or for the application of joining materials may be used in the production of electronic products, in particular when using SMD components. Solder/sinter paste or adhesives for example are thereby used as joining materials. So far, only individual units have been tested. The testing of individual units is not very meaningful here with respect to the interaction within the entire assembly line.

### SUMMARY

The teachings of the present disclosure allow the detection of process parameters over an entire assembly line. For example, some embodiments of the teachings herein include a device (100) for detecting process parameters during a pass through an assembly line (500) for assembling electronic components and/or for applying joining materials, having: a carrier (120), which is designed for being transported by a conveying system (560) of the assembly line (500) and for receiving a test plate (110), and at least one sensor (F, E, A, T) for measuring at least one process parameter during the pass, having one or more force sensors (F), which are arranged such that a force and/or force distribution that acts on the test plate (110) during the pass can be detected.

In some embodiments, there is a climate sensor (E), which is designed for detecting temperature and/or atmospheric humidity.

In some embodiments, there is an acceleration sensor (A), which is designed for detecting the acceleration of the device (100) that acts on the device (100) during a pass through the assembly line (500).

In some embodiments, there is an optical sensor (CM), which is arranged such that it can detect an application of joining material from below a covering and/or the test plate (110).

In some embodiments, there are fiducial and/or register marks (M).

In some embodiments, there is at least one identification marking (QR).

In some embodiments, there is at least one temperature sensor (T).

In some embodiments, there is a communication interface (COM).

In some embodiments, there is an energy supply device (EV).

In some embodiments, there is a data memory and/or an evaluation unit.

In some embodiments, there is a test plate (110).

In some embodiments, the test plate (110) is a printed circuit board.

In some embodiments, the test plate (110) has a touch-sensitive surface.

In some embodiments, the test plate (110) has test locations which are designed such that an application of solder paste of inferior quality is produced and/or simulated.

### BRIEF DESCRIPTION OF THE DRAWINGS

Various embodiments of the present disclosure are described and explained in more detail below on the basis of the exemplary embodiments that are represented in the figures, in which:

FIG. 1 shows an embodiment of a device incorporating teachings of the present disclosure; and

FIG. 2 shows an assembly line incorporating teachings of the present disclosure.

### DETAILED DESCRIPTION

Various embodiments of the teachings herein include a device for detecting process parameters during a pass through an assembly line is proposed. The device has for this purpose a carrier, which is designed for being transported by a conveying system of the assembly line and for receiving a test plate. The device also has at least one sensor for measuring at least one process parameter during the pass. The conveying system extends through the entire assembly line and so the device can pass through the assembly line like a real product and thereby continuously detect and record corresponding process-relevant characteristic data. The great advantage is that parameters can be detected under production conditions. In a further step, parameters of the assembly line can be adapted in order to bring about a considerable influence on the quality of the assembly line or the end products.

In some embodiments, such a device is used in the case of an SMD assembly line and can be used for example for the determination of accelerations and/or vibrations of the transporting modules. It is also possible in stencil printing for a force distribution during the squeegeeing, the climatic conditions, that is to say the temperature and/or atmospheric humidity in the device, the temperature of the printed medium and the positioning accuracy of the stencil to be detected. In the case of mounting machines, the accelerations and vibrations can likewise be detected, as well as the mounting forces that act on the test plate or other structural elements. Here it is possible to carry out a test run of a program for various pipettes or mounting heads. The positioning accuracy or the actual positioning of the components that are positioned on the test plate can also be assessed. For dispensing machines or so-called dispensers it is possible to detect accelerations and/or vibrations, the temperature of the dispensed medium, the climatic conditions (temperature and/or atmospheric humidity in the device) in the dispenser and the positioning accuracy of the dispenser.

In some embodiments, the device has one or more force sensors, which are arranged such that a force and/or force distribution that acts on the test plate during the pass can be detected. In particular, the force distribution of a squeegee in the stencil printing of a solder paste for example is of interest here. It may also be of interest to detect force peaks at individual locations and possibly to prevent damage to the printed circuit board on which components are to be mounted or damage to components.

In some embodiments, the device has a sensor for detecting temperature and/or atmospheric humidity. This is designed for detecting temperature and/or atmospheric humidity. The climate sensor may also be designed for detecting dusts or fine dusts, in order to determine whether there is inadmissible pollution with such dusts and possibly to be able to determine the sources of the contaminants.

In some embodiments, the device has an acceleration sensor for detecting the acceleration of the device. The accelerations that act on the device during a pass through the assembly line correspond to the accelerations that also act on a real printed circuit board while it passes through the process. Here, for example, sections with an acceleration that is too high can be identified, in order possibly to prevent slipping of structural elements or to improve sections with an acceleration that is too low, in order to achieve an optimization of the passing-through time.

In some embodiments, the device has an optical sensor. The optical sensor is in this case arranged such that it can detect an application of joining material from below a covering and/or the test plate. For this purpose, it may be expedient that at least part of the covering or of the test plate is of a transparent design, so that the application of joining material can be assessed well from below. This has the great advantage that the application of joining material to a surface that is otherwise covered by the solder paste itself can be assessed. The optical sensor may in this case be designed as a camera, which can for example determine an offset of the dispensed material or of a needle tip of a dispensing system.

In some embodiments, the device has fiducial and/or register marks. Such marks serve for detecting the alignment of the device and are usually applied to printed circuit boards in order that they can pass through the process in the correct alignment. Such marks are used in particular for the accurate positioning of components that are positioned in relation to a number of marks. This also allows a high level of positioning accuracy to be achieved and tested on the device.

In some embodiments, the device has at least one identification marking. Such an identification device may be designed for example as a machine-readable code, for example a barcode or a QR code. The device can thus always be clearly identified and thus a clear identification can be left in the detected process parameters to facilitate later evaluation.

In some embodiments, there is a temperature sensor, in particular a surface thermocouple. The surface thermocouple may in this case be used for the purpose of positioning pastes or other materials directly onto the surface of the thermocouple and detecting the temperature of the medium directly when there is contact with the surface.

In some embodiments, the device has a communication interface. This may be designed as a wire-bound communication interface. If the device has a memory, the memory can be read via the communication link. The device may also have a wireless interface, which allows the data to be sent from the device for evaluation in real time.

In some embodiments, the device has an energy supply device. The energy supply device is in this case preferably designed to provide at least the energy for the sensors for at least one pass. This similarly includes the recording of the sensor data as well as any potential communication of the sensor data to the outside. Storage batteries may be used here for example.

In some embodiments, the device has a data memory and/or an evaluation unit. Depending on the place of use of the device, it may be advantageous to store the sensor data permanently in the device and to have the data available for later evaluations at another location. In some embodiments, an evaluation unit accesses a data memory directly and carries out first evaluations of quality criteria immediately, for example to indicate them directly. An indication may in this case take place by way of a display directly on the device but may similarly be forwarded to an evaluation device by way of a wireless or wire-bound communication interface.

In some embodiments, there is a system comprising a device as described herein and a test plate. The embodiments mentioned may in this case be combined with one another and supplement one another. An acceleration sensor together with the force sensors may generate an accurate force-acceleration profile. Vibrations can similarly be detected here. The test plate may in this case be designed as a glass plate, which can be cleaned well and also has the advantage of being optically transparent. Other materials that have a good surface finish and cleanability are also conceivable. Test plates may in this case also be designed as disposable test plates, which after use as a test plate are archived or passed on to a further processing step.

In some embodiments, the test plate is designed as a printed circuit board. Commercially available printed circuit boards can be received in the receptacle of the device, in order then to test under conditions that come close to real conditions. Here it is possible that the printed circuit board already has sensors, which can be contacted by way of the receptacle of the device and which can thus also deliver measured values.

In some embodiments, the test plate has a touch-sensitive surface. This may be designed for example like a touch element of a touch screen. For this purpose, capacitive, inductive or resistive processes are conceivable. The advantage of this is that the positioning of individual elements can be detected. Since, for example, solder paste is electrically conducting, detection by way of a capacitive process is possible without any problem.

In some embodiments, the test plate has test locations which are designed such that an application of solder paste of inferior quality is produced or simulated. An inferior application of solder paste serves for testing solder paste inspection systems (also known as SPIs), in order for example to verify whether an error message is triggered if an inferior application of solder paste is detected, or whether it is detected at all. In order to produce an application of solder paste of inferior quality, the surface of the test plate may have irregularities or the inferior application of solder paste may be simulated by test dummies on which components can be mounted and which have irregularities.

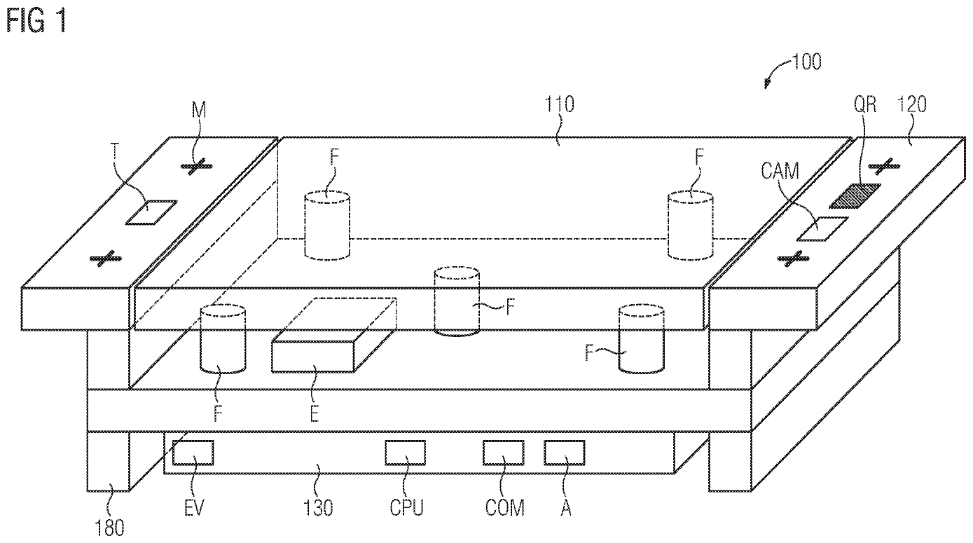

FIG. 1 shows an embodiment of a device 100 with a test plate 110. The device 100 has a well-shaped carrier 120. The carrier 120 in this case stands on two supporting elements 180, which are designed here as feet and protect electronics arranged on the underside of the device. The carrier 120 is in this case designed such that it can be transported with or without supporting elements 180 by a transporting system of an assembly line and can also be processed by the individual process steps to be checked. Thus, the test plate 110 is designed such that it can for example be provided with solder paste by a squeegee printing process and on which SMD components can be mounted by a mounting machine.

The test plate 110 is in this case arranged on five force sensors F. The force sensors F are in this case arranged in such a way as to allow an image that is as complete as possible of a force distribution, for example of the squeegee used for the application of a solder paste in a screen printing process. The device 100 also has a climate sensor E, which detects the environmental conditions with respect to temperature and atmospheric humidity. Arranged underneath the carrier 120 is an electronics module 150, which has a processor CPU, an energy supply device EV and also an acceleration sensor A. The electronics module 150 may in this case also be integrated in the carrier 120.

The carrier 120 has marks M, which are arranged in the corners of the carrier 120 and allow an exact alignment of the carrier. The device 100 also has an identification marking QR, which may for example be designed as a QR code. The identification marking may in this case be indicated for example by means of an e-paper display and can be changed from pass to pass. The device 100 also has a surface thermocouple T, that is to say a temperature sensor, which detects the temperature at the surface of the device 100, and consequently for example the temperature of a medium applied to the sensor.

An optical sensor CAM is attached underneath a glass sheet in the carrier 120, it being possible for dispensing tests to be carried out on this part of the carrier. It is similarly conceivable that parts of the test plate 110 are of a transparent design and the optical sensor CAM or other sensors are arranged underneath the test plate.

The carrier 120 and the test plate 110 may in this case also be of a one-part design, i.e. the carrier 120 and the test plate 110 may be a monolithically constructed.

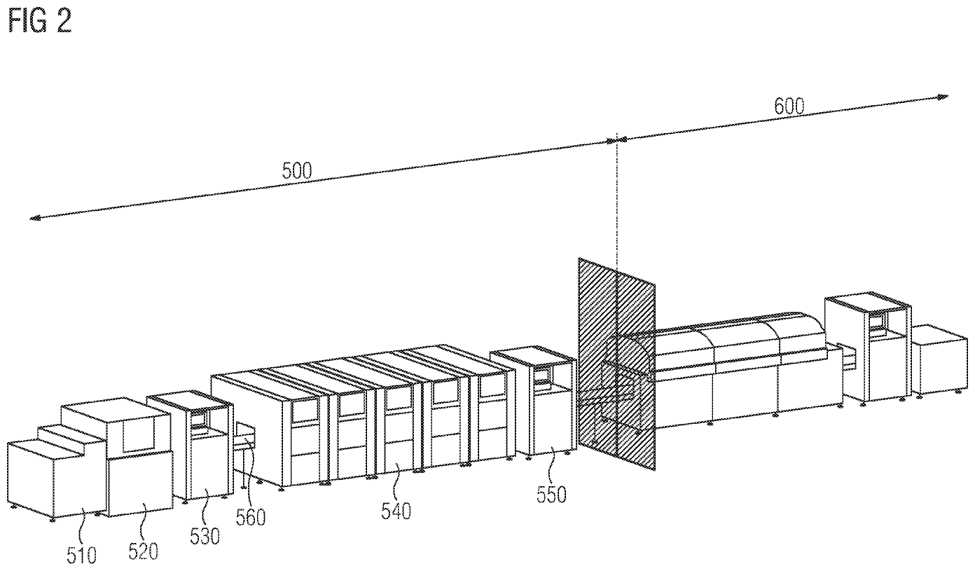

FIG. 2 shows an assembly line 500, followed by a soldering installation 600. The device 100 is in this case intended to be used in the assembly line 500, to detect its parameters and to contribute to the improvement of the parameters. A PCB store 510 serves for storage of bare PCBs or other substrates. A stencil printing machine 520 serves for printing solder paste onto the PCBs. A solder paste inspection 530 (SPI) inspects whether the solder paste has been applied as expected. One or more mounting machines 540 place the components on the PCB or the soldered locations. Provided as the last step before the reflow soldering in this case is an automated optical inspection 550 (in this case a pre-reflow AOI). Since the assembly line 500 is space-optimally constructed, a transporting system 560 can only be seen between the solder paste inspection 530 and the mounting machine 540, but the transporting system 560 extends through the entire assembly line 500 and can accordingly transport the device 100 through the assembly line 500.

To sum up, the present disclosure describes various devices (100) designed for detecting process parameters during a pass through an assembly line (500) for assembling electronic components and/or for applying joining materials. In order to allow the detection of process parameters over an entire assembly line, the device has a carrier (120), which is designed for being transported by a conveying system (560) of the assembly line (500) and for receiving a test plate (110), and at least one sensor (F, E, A, T) for measuring at least one process parameter during the pass. The disclosure also relates to various systems comprising a device (100) and a test plate (110).

What is claimed is:

1. A device for detecting process parameters during a pass through an assembly line for assembling electronic components and/or for applying joining materials, the device comprising:
a carrier for transport by a conveying system of the assembly line and configured to receive a test plate;
a sensor for measuring a process parameter during the pass; and
a force sensor arranged to detect a force acting on the test plate during the pass.

2. The device as claimed in claim 1, further comprising a climate sensor for detecting temperature and/or atmospheric humidity.

3. The device as claimed in claim 1, further comprising an acceleration sensor for detecting the acceleration of the device during a pass through the assembly line.

4. The device as claimed in claim 1, further comprising an optical sensor arranged to detect an application of joining material from below a covering and/or the test plate.

5. The device as claimed in claim 1, further comprising fiducial and/or register marks.

6. The device as claimed in claim 1, further comprising an identification marking.

7. The device as claimed in claim 1, further comprising a temperature sensor.

8. The device as claimed in claim 1, further comprising a communication interface.

9. The device as claimed in claim 1, further comprising an energy supply.

10. The device as claimed in claim 1, further comprising a data memory and/or an evaluation unit.

11. A system comprising:
a test plate; and
a device for detecting process parameters during a pass through an assembly line for assembling electronic components and/or for applying joining materials, the device comprising:
a carrier for transport by a conveying system of the assembly line and configured to receive a test plate;
a sensor for measuring a process parameter during the pass; and
a force sensor arranged to detect a force acting on the test plate during the pass.

12. The system as claimed in claim 11, wherein the test plate comprises a printed circuit board.

13. The system as claimed in claim 12, wherein the test plate includes a touch-sensitive surface.

14. The system as claimed in claim 12, wherein the test plate includes test locations with an application of solder paste of inferior quality.
